(19) United States
(12) Patent Application Publication
(10) Pub. No.: US 2013/0109290 A1
(43) Pub. Date: May 2, 2013

(54) FORCED AIRFLOW CONTROL DEVICE AND METHOD OF OPERATION

(71) Applicant: Raytheon Company, Walsham, MA (US)

(72) Inventors: Daniel P. Jones, Pinellas Park, FL (US); Millage G. Burnsed, St. Petersburg, FL (US)

(73) Assignee: RAYTHEON COMPANY, Walsham, MA (US)

(21) Appl. No.: 13/661,805

(22) Filed: Oct. 26, 2012

Related U.S. Application Data
(60) Provisional application No. 61/552,204, filed on Oct. 27, 2011.

(51) Int. Cl. F24F 13/10; F24F 11/053; H05K 5/02

(52) U.S. Cl. 454/184; 454/333; 454/258

(57) ABSTRACT

According to one embodiment, a forced airflow control device includes multiple one-way valves for a corresponding multiple fans. The fans are configured to provide an airflow to an enclosure of a housing. Each one-way valve is mounted over a port of its corresponding fan and configured to restrict the movement of the airflow to only one direction through the port of its respective fan.

### CROSS-REFERENCE TO RELATED APPLICATION(S) AND CLAIM OF PRIORITY

The present application claims priority to U.S. Provisional Patent Application Ser. No. 61/552,204 filed Oct. 27, 2011, entitled “FORCED AIRFLOW CONTROL DEVICE”. The content of the above-identified patent documents is incorporated herein by reference.

### TECHNICAL FIELD

This disclosure relates generally to thermal management systems. More specifically, this disclosure relates to a forced airflow control device and method of operation.

### BACKGROUND

Electronic circuit assemblies are often stored in housings for several reasons including protecting the assembly from physical damage, providing a barrier to electro-magnetic interference (EMI) generated inside or outside of the housing, and/or providing a structure for mounting of the assembly. Housings, such as these, are often referred to as chassis and are generally formed of bent metal or molded plastic. These housings may be designed according to the environments in which the housed electronic circuit assemblies may be used. In many instances, the electronic circuit assemblies generate heat that, if not abated using fans or other thermal conveyance techniques, may cause overheating and eventual damage to the electronic circuit assemblies.

### SUMMARY

This disclosure provides a forced airflow control device and related system and method.

In a first embodiment, a forced airflow control device includes multiple one-way valves for a corresponding multiple fans. The fans are configured to provide an airflow to an enclosure of a housing. Each one-way valve is mounted over a port of its corresponding fan and configured to restrict the movement of the airflow to only one direction through the port of its respective fan.

In a second embodiment, a thermal management system includes a housing having multiple fans that are configured to cool elements in the housing. Each fan comprising a port through which the fan forces air into the housing. Each fan is configured with a one-way valve. Each one-way valve mounted over the port of its corresponding fan and configured to restrict the movement of air through to only one direction through the port of the fan.

In a third embodiment, a thermal management method includes providing multiple fans that are configured to cool elements in a housing. Each fan comprising a port through which the fan forces air into the housing. Each fan is configured with a one-way valve. Each one-way valve mounted over the port of its corresponding fan and configured to restrict the movement of air through to only one direction through the port of the fan. The method further includes selectively turning on or off, one or more of the fans to control a temperature of the one or more components inside the housing.

Certain embodiments may provide various technical advantages depending on the implementation. For example, certain embodiments of the one-way valves may provide an advantage of reduced backflow through their respective fans to provide more efficient cooling of the housing when only a portion of the fans are turned off. In some cases, it may be beneficial to use multiple fans for active cooling of an enclosure within a housing. Nevertheless, a problem may be encountered when one of multiple fans fails or is turned off, such as via control by a thermostat. Specifically, the port of a fan that is not running may allow at least part of the airflow generated by other running fans to exit the housing without providing any substantial cooling effect to the enclosed space within the housing.

In according with this disclosure, a forced airflow control device includes multiple fans, each of which is configured with a one-way valve for restricting the movement of air to substantially only one direction through a port with which it is associated. That is, when each fan is active, its respective one-way valve is open and when the fan is inactive, its respective one-way valve is closed. The latter case may provide relatively more efficient cooling at hot temperatures and more efficient heating at low temperatures. This is accomplished by stopping or reducing air recirculation when one or more valves are closed for hot ambient conditions and stopping or reducing cold air intrusion into the volume when all valves are closed and all fans are inactive in cold ambient conditions. The multiple fans may be configured on a housing to provide active airflow through an enclosure of the housing.

Other technical features may be readily apparent to one skilled in the art from the following figures, descriptions, and claims.

### BRIEF DESCRIPTION OF THE DRAWINGS

For a more complete understanding of this disclosure, reference is now made to the following description, taken in conjunction with the accompanying drawings, in which:

FIG. 1 illustrates an example forced airflow control device for controlling airflow through an enclosed housing according to certain embodiments of this disclosure;

FIGS. 2A through 2C illustrate example operational positions of an embodiment of a forced airflow control device according to certain embodiments of this disclosure;

FIG. 3 illustrates another example forced airflow control device having multiple one-way valves that may be configured over the ports of corresponding multiple fans according to certain embodiments of the present disclosure;

FIG. 4 illustrates an example controller that may be used for controlling the operation of the forced airflow control device according to certain embodiments of this disclosure; and

FIG. 5 illustrates an example process that may be performed by the forced airflow control device according to embodiments of the present disclosure.

### DETAILED DESCRIPTION

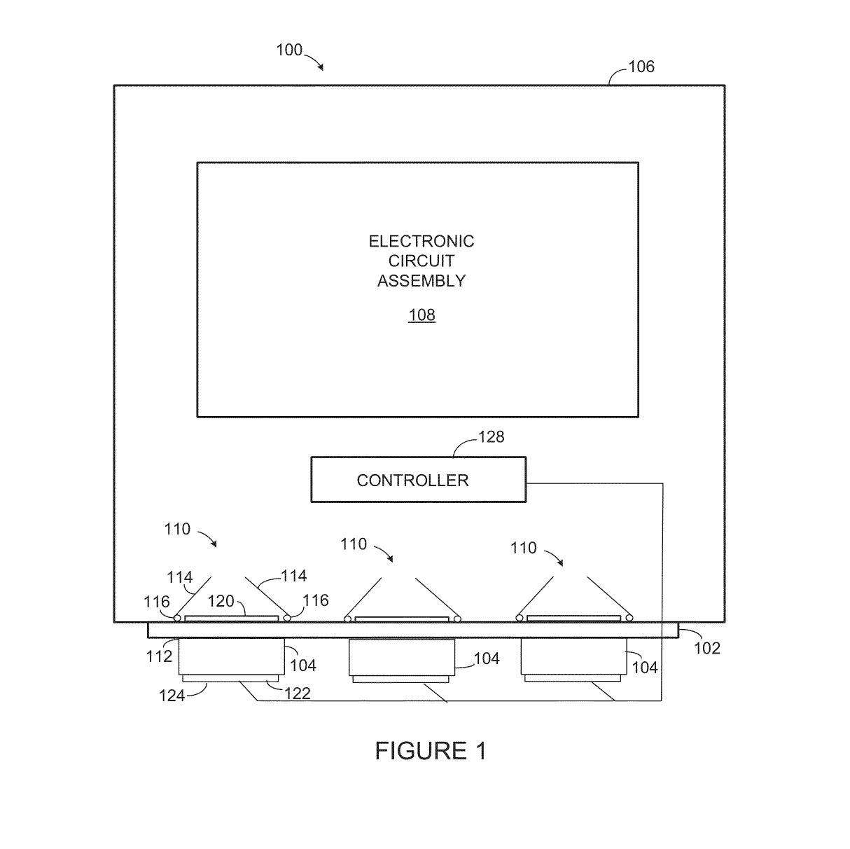

FIGS. 1 through 5, discussed below, and the various embodiments used to describe the principles of the present invention in this patent document are by way of illustration only and should not be construed in any way to limit the scope of the invention. Those skilled in the art will understand that the principles of the invention may be implemented in any type of suitably arranged device or system.

FIG. 1 illustrates an example forced airflow control device 100 for controlling airflow through an enclosed housing according to this disclosure. In the following description, reference is made to a housing that houses an electronic circuit assembly. However, the device 100 could be used for controlling the airflow to an enclosed housing that houses any suitable device or system to receive active cooling using two or more fans.

As described above, electronic circuit assemblies are often housed in housings commonly referred to as chassis for several reasons that may include providing physical protection from the environment in which the electrical assemblies are used and/or to provide electrical isolation of the enclosed electronic circuit assemblies from the harmful effects of electro-magnetic interference (EMI). Nevertheless, these housings also form a barrier to the natural convective movement of air such they trap heat generated by the electronic circuit assemblies that they house.

Several techniques have been developed to remedy this problem. One conventional technique has been to use thermal conveyance devices such as heat pipes that convey heat from the inside to the outside of the housing. This conveyance of heat uses a channel of phase-change material that boils in the presence of internal heat to absorb heat from the electrical assembly and condenses outside of the housing to dissipate heat outside of the housing. Another conventional technique includes one or more fans that are configured to provide a continual supply of fresh, cooled air within the enclosure of the housing. This particular technique is also generally referred to a active cooling because an external source of power is provided to the fans to cause the continual movement of air through the housing.

In some cases, it may be beneficial to use multiple fans for active cooling of an enclosure within a housing. For example, space constraints associated with the housing may preclude the use of one single large fan, which may be relatively bulky and may not conform to the overall physical profile of the housing for which it is intended to cool. As another example, computer fans have been developed that are well suited for use with electronic circuit assemblies configured within enclosed housings. Fans such as these have a box-like shape and are generally identified by the diameters of their respective impellers, such as 80 mm fans having an impeller diameter of 80 millimeters.

Certain embodiments using multiple fans may also be beneficial for controlling a temperature within an enclosure of the housing. For example, a thermostat controller may be configured to turn off one or more of the multiple fans such that airflow may be proportionally decreased. For example, a particular forced airflow control device having three fans may be controlled, using a thermostat, to turn off one of the fans such that overall resulting airflow is approximately 66 percent of the airflow provided by all three fans.

Nevertheless, a problem may be encountered when one of multiple fans fails or is turned off, such as via control by a thermostat. Specifically, the port of a fan that is not running may allow at least part of the airflow generated by other running fans to exit the housing without providing any substantial cooling effect to the enclosed space within the housing.

In according with this disclosure, a forced airflow control device includes multiple fans, each of which is configured with a one-way valve for restricting the movement of air to substantially only one direction through a port with which it is associated. The multiple fans may be configured on a housing to provide active airflow through an enclosure of the housing.

As shown in FIG. 1, the device 100 includes a panel 102 in which multiple fans 104 may be mounted. The device 100 is mounted on a housing 106 that houses one or more components that in this particular embodiment, is an electronic circuit assembly 108. The electronic circuit assembly 108 may include one or more circuit boards that generate heat during its use. For example, the electronic circuit assembly 108 may include one or more active devices such as transistors that are configured to amplify an input radio-frequency (RF) signal to produce an output RF signal having a suitable power level for transmission through an antenna.

The device 100 also includes multiple one-way valves 110 configured over outlet ports 112 of the fans 104. The valves 110 restrict the movement of air to substantially only one direction through their respective ports 112. Each one-way valve 110 of this particular embodiment includes a pair of flaps 114 that articulate from a closed position to an open position via hinges 116. When in the closed position, the flaps 114 lie essentially adjacent to the panel 102 and function to restrict movement of air through the port 112 of its respective fan 104. When in the open position, the flaps 114 are rotated away from the panel 102 to allow air to flow through the port 112 of its respective fan 104.

The flaps 114 may be controlled to open or close in any suitable manner. In some embodiments, each flap 114 may be biased in the closed position using a spring (not shown) having sufficient tension to maintain its flap 114 adjacent to the port 112 under a “no airflow” condition, while allowing the flap 114 to rotate to the open position when its fan 104 is actively generating an airflow. The spring used to bias each flap 114 to the closed position may be formed from any suitable material(s), such as a coiled metallic spring or a polymer material like neoprene or other similar resilient polymer material. In other embodiments, each flap 114 may be biased to the closed position using gravity such that the weight of each flap 114 causes movement to the closed position when no active airflow is generated through the port 112 of its respective fan 104.

In some embodiments, a seal 120 may be provided over the port 112 of each fan 104 such that the flaps 114 rest on the seals 120 when in the closed position. In particular embodiments, the seals 120 may reduce bypass leakage of air when the flaps 114 are in the closed position.

In the particular embodiment shown, the one-way valves 110 are configured on the outlet port 112 of the fans 104. In other embodiments, the one-way valves 110 may configured on an input port 122 of each fan 104. Also, each fan 104 may include a filter 124 that filters dust and other airborne debris from entering the enclosure of the housing 106.

The fans may be controlled in any suitable manner to provide a fresh flow of air into or out of the enclosure of the housing. In the particular embodiment shown, the forced airflow control device 100 includes a controller 128 coupled to the fans 104 and configured to control their operation. In another embodiment, the fans 104 may be configured to run at all times when the electronic circuit assembly is operating. Operation of the forced airflow control device 100 will be explained in detail below.

Although FIG. 1 illustrates one example of a forced airflow control device 100 for controlling airflow through an enclosed housing, various changes may be made to FIG. 1. For example, the fans 104 may be configured to pull air from the housing 106 rather than push air into the housing 106 as shown in FIG. 1. As another example, although each one-way valve 110 shown in FIG. 1 includes two flaps 114 for selectively covering the ports 112 of their respective fans 104, each one-way valve 110 may include any number of flaps 114, such as one flap or three or more flaps. As yet another example, although the flaps 114 are shown as rotatable from a closed position to an open position using hinges, other articulatable mechanisms may be used, such as flexible plastic members that secure the flaps to the panel. Additionally, these flexible plastic members may be integrally formed with their respective flaps.

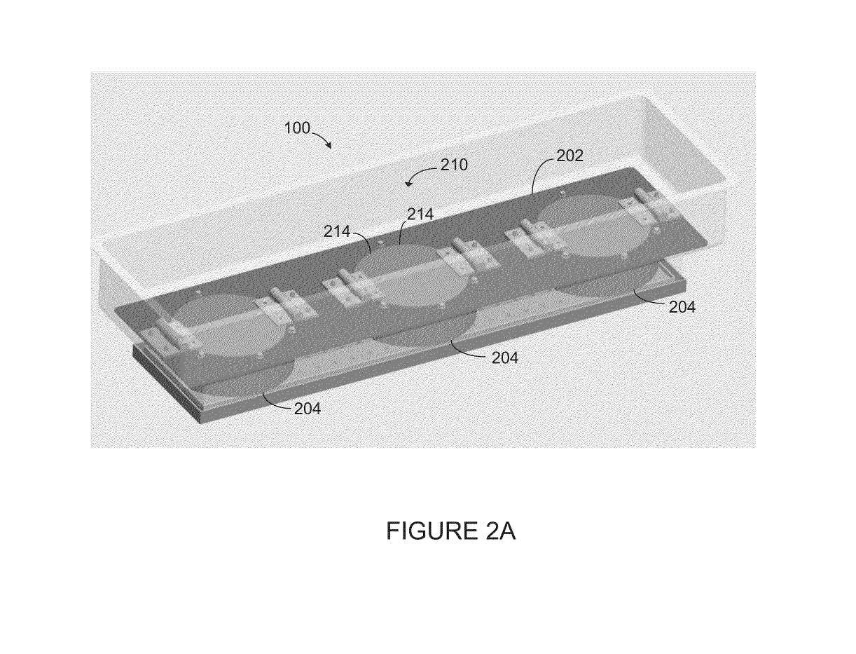

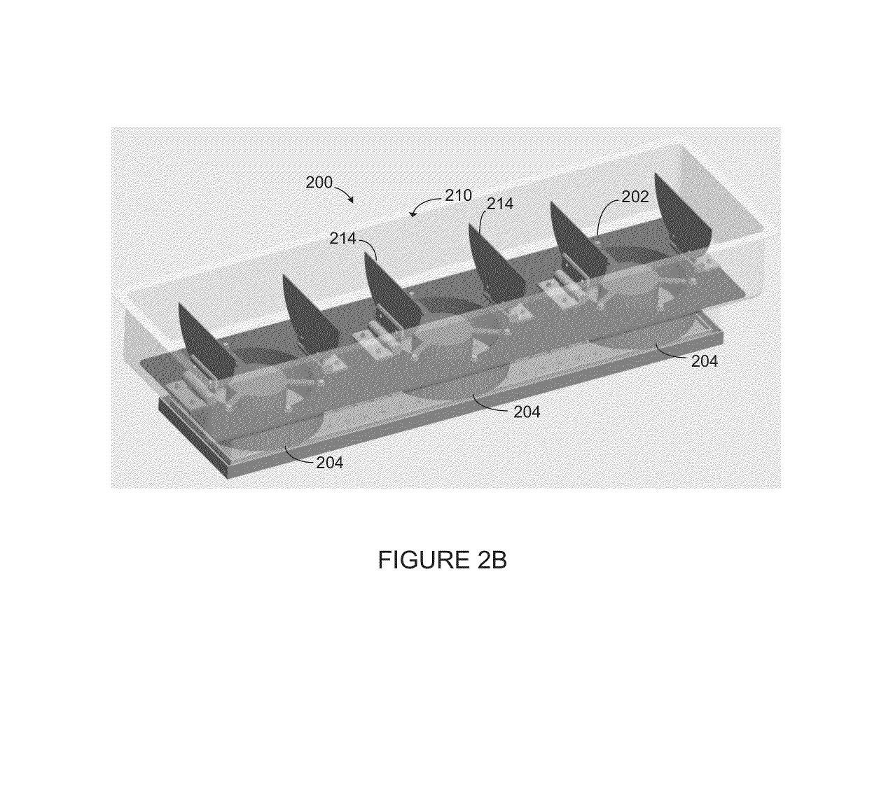

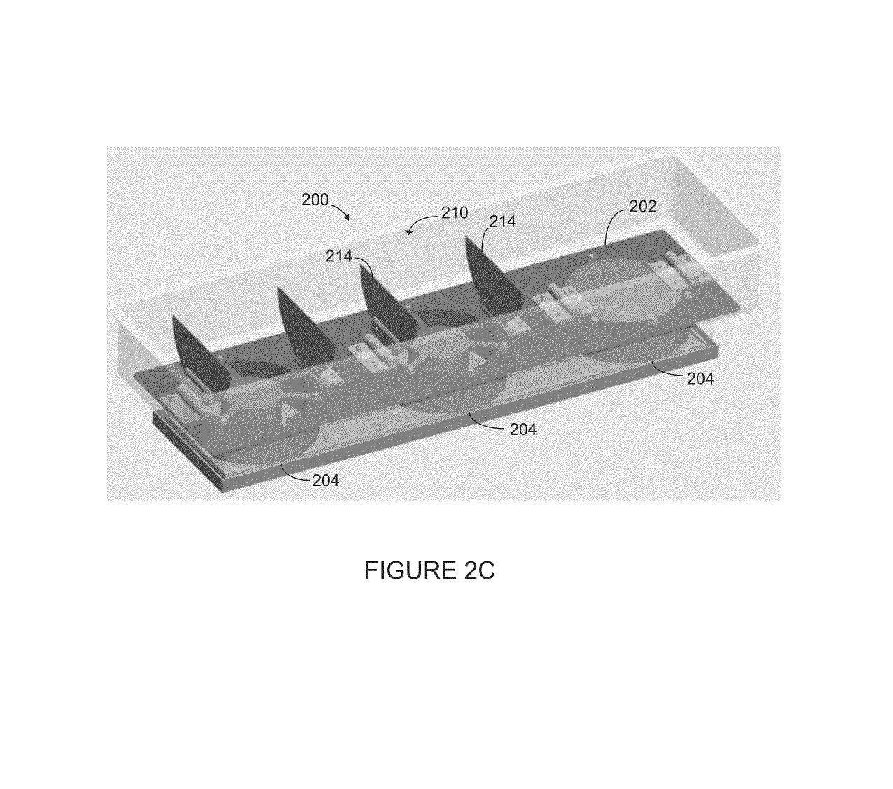

FIGS. 2A through 2C illustrate example operational positions of an embodiment of a forced airflow control device 200 according to this disclosure. As shown in FIG. 2A, the forced airflow control device 200 includes multiple one-way valves 210 mounted on a panel 202. Each one-way valve 210 has a pair of flaps 214 that are configured in a closed position over an outlet port of a fan 204. When in the closed position, the flaps 214 cover the ports of their respective fans 204 such that air movement through each fan 204 is reduced.

As shown in FIG. 2B, the flaps 214 are in an open position. The airflow generated by each fan 204 may generate sufficient force to move the flaps 214 from the closed position to the open position. In some embodiments, each flap 214 may be spring-loaded to bias the flap 214 in the closed position. In other embodiments, the flaps 214 may be biased in the closed position using gravity or other mechanism.

FIG. 2C illustrates a particular operational position of the one-way valves 210 in which the flaps 214 of one valve 210 are in the closed position due to its respective fan 204 having ceased operation. This condition may be caused due to several reasons, such as failure of its respective fan or by an action caused by the controller 128 that selectively removes electrical power to the fan. In this case, two remaining fans 204 that are operational provide airflow to the enclosed portion of a housing 206 without significant bypass airflow escaping through the port of the fan 204 that has ceased operation.

Although FIGS. 2A through 2C illustrate examples of operational positions of an embodiment of a forced airflow control device 200, various changes may be made to FIGS. 2A through 2C. For example, although the flaps 214 are shown as having being generally rigid and movable over the ports of the fans 204 via rotation about hinges, other embodiments may incorporate flexible flaps, flaps formed of plastic that are rotatable about an integrally formed hinge, or other mechanisms. Additionally, the forced airflow control device 200 may include other elements, such as a filter 224 to filter the air used to cool the enclosed space within the housing 206.

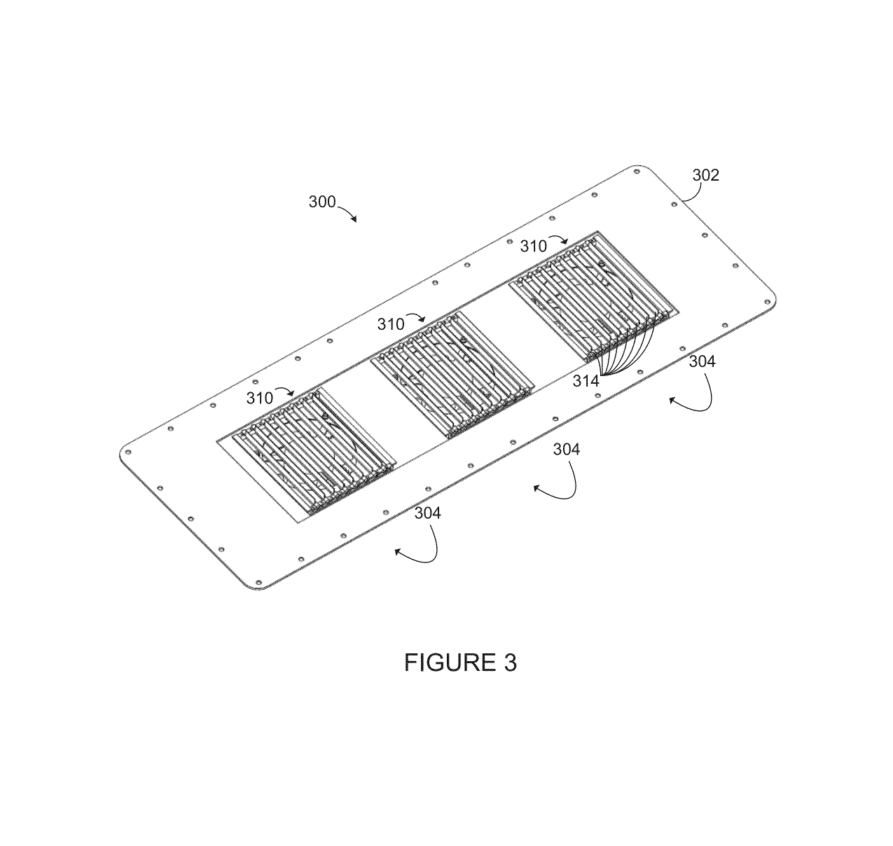

FIG. 3 illustrates another example forced airflow control device 300 having multiple one-way valves 310 that may be configured over the ports of a corresponding multiple fans 304 according to certain embodiments of the present disclosure. The one-way valves 304 are similar to the one-way valves 110 of FIG. 1 in that they are each configured over a port of a fan 304 for restricting movement of air through the port of each respective fan in only one direction. The one-way valves 304 differ, however, in that each one-way valve 304 includes multiple flaps 314 that are arranged in parallel relative to one another.

Each flap 314 is hingedly attached to a panel 302 such that it may articulate from a closed position in which the movement of air is restricted to an open position in which air movement through its associated fan is allowed.

Certain embodiments incorporating a one-way valve 310 as shown may provide an advantage in that the multiple flaps 314 may have a reduced profile and thus reduced clearance requirements for other components in the housing when in the open position. For example, the one-way valve 110 shown in FIG. 1 having only two flaps 114 may require a clearance above the panel 102 that is approximately ½ of the port diameter because the flaps 114 may rotate 90 degrees between the closed position and the open position. The multi-flap design as shown in FIG. 3, however, may have a reduced clearance requirement due to their relatively shorter height when in the open position.

Although FIG. 3 illustrates an example embodiment of one-way valves 310 that may be used with the forced airflow control device, various changes may be made to FIG. 3. For example, although the flaps 310 are shown as being hingedly attached to the panel 302 along an axis perpendicular to the longer edge of the panel 302, other embodiments of the flaps 310 may be hingedly attached to the panel 302 along an axis that is parallel to the longer edge of the panel 302.

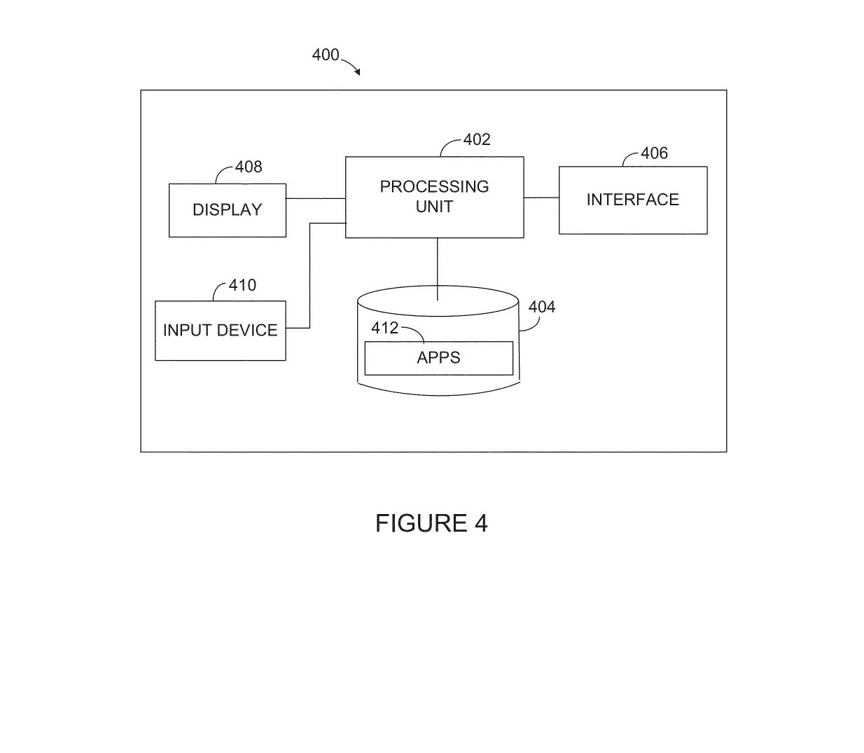

FIG. 4 illustrates an example controller 400 that may be used for controlling the operation of the forced airflow control device according to this disclosure. Although specific details and components will be shown for a particular controller, in other configurations, the controller may have more, less, or different components. As shown in FIG. 4, the controller 400 includes at least one processing unit 402, at least one memory unit 404, and an interface 406. In certain embodiments, the controller 400 may also include a display 408, and an input device 410.

The processing unit 402 represents any suitable processing device(s), such as a microprocessor, microcontroller, digital signal processor, application-specific integrated circuit, field programmable gate array, or other logic device. The memory unit 404 represents any suitable volatile and/or non-volatile storage and retrieval device(s), such as random access or read-only memory.

The interface 406 represents any suitable interface for facilitating communication over one or more networks, such as an Ethernet interface or other electrical signal line interface or a wireless interface. For example, the interface 406 can be used to receive instructions for controlling operations of the thermal management system from other controllers, such as a satellite controller that controls the overall operation of the platform 100. The display 408 represents any suitable display device for presenting information to a user. The input device 410 represents any suitable device(s) for receiving input from a user, such as a keyboard or mouse. For example, the input device 410 may be used to provide user input that directs the operation of the forced airflow control device by a user.

In FIG. 4, the memory unit 404 includes at least one executable application 412. The application 412 represents one or more computer programs defining how the controller 400 controls operation of the forced airflow control device. For example, the application 412 may receive signals representing temperature measurements of certain thermally sensitive components inside the housing and manipulate power to the fans according to these received measurements. This adjustment could be performed on a one-time basis or on a continual, on-going basis. The application 412 could also include instructions for other features, such as generating an alarm if the measured temperatures of these thermally sensitive components fall outside of their expected limits.

Although FIG. 4 illustrates one example of a controller 400 for controlling operation of the forced airflow control device, various changes may be made to FIG. 4. For example, the controller 400 could include any other or additional components according to particular needs. Also, the controller 400 could be implemented using any suitable monitoring or control technology. In addition, the controller 400 could be used to control one or multiple forced airflow control devices.

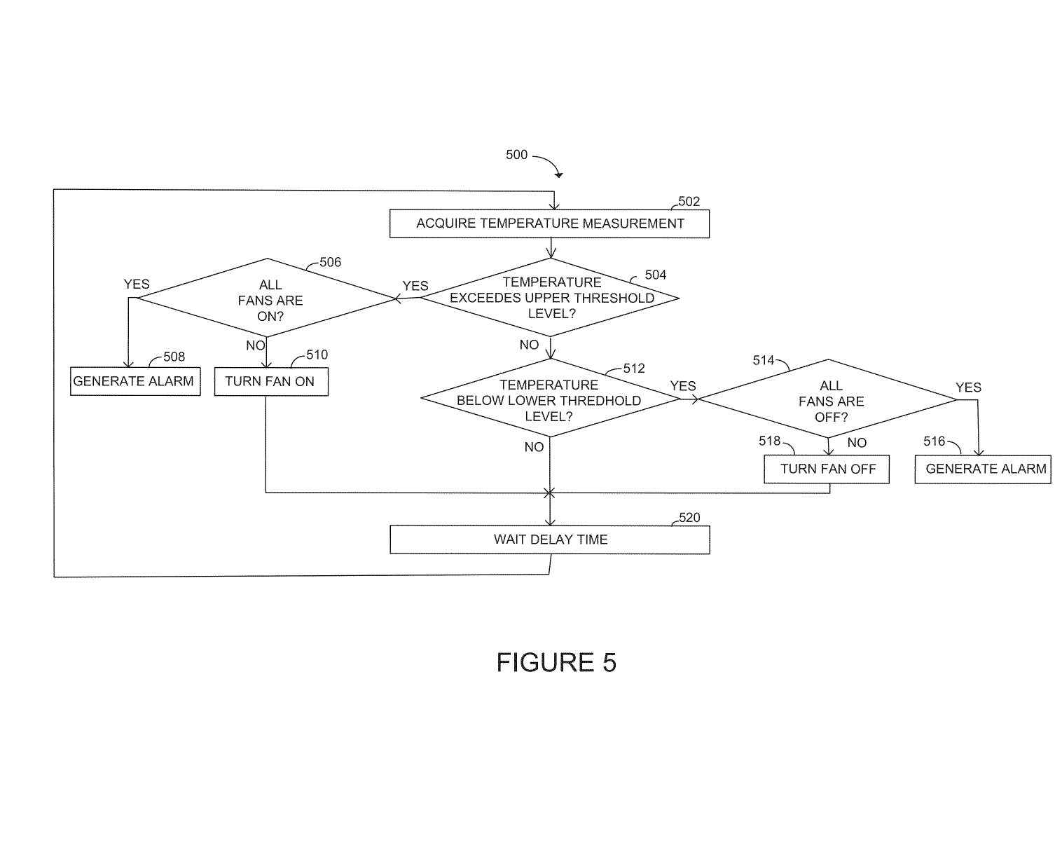

FIG. 5 illustrates an example process that may be performed by the forced airflow control device according to embodiments of the present disclosure.

At step 502, the controller acquires a measurement of the temperature inside of a housing on which a forced airflow control device is configured. The measurement may be acquired in any suitable manner, such as via a thermocouple having two dissimilar materials that generate a voltage signal proportional to the temperature inside the housing.

At step 504, the controller determines whether the temperature levels inside the housing have exceeded an upper threshold value. If so, the controller continues operation at step 506, otherwise, the controller continues operation at step 510,

At step 506, the controller further determines whether all fans are currently powered on. Essentially, a condition in which all fans are currently powered on may be interpreted to mean that the maximum cooling capacity of the forced airflow control device has reached its maximum level given the current ambient conditions and the operating conditions of components inside the housing. Stated another way, when all fans are currently in the on state and the temperature inside the housing has exceeded the upper threshold, a thermal runaway condition exists. Thus, if all fans are determined to be powered on, operation continues at step 508 in which the controller generates an alarm to alert users to the thermal runaway condition. However, if all fans are not powered on, the controller continues operation at step 510 in which at least one additional fan that has been powered off, is powered on. The additional airflow provided by the newly powered on fan provides additional cooling capacity for cooling the components inside the housing.

At step 512, the controller determines whether the temperature levels inside the housing have been reduced below a lower threshold value. If so, the controller continues operation at step 514, otherwise, the controller continues operation at step 520.

At step 514, the controller further determines whether all fans are currently powered off. A condition in which all fans are currently powered off may be interpreted to mean that the forced airflow control device is providing essentially no cooling effect to the components inside the housing. That is, when all fans are currently in the off state and the temperature inside the housing is below the lower threshold, the forced airflow control device is no longer actively controlling the temperature inside the housing. Thus, if all fans are determined to be powered off, operation continues at step 516 in which the controller generates an alarm to alert users to the overly low temperature condition inside the housing. However, if all fans are not powered off, the controller continues operation at step 518 in which at least one additional fan that has been powered on, is powered off. The reduced airflow provided by turning off at least one fan may, in turn, reduce the cooling capacity for maintaining the temperature inside the housing above the lower threshold value.

At step 520, the controller waits for a specified delay time. This delay time value may be selected such that thermal levels inside the housing may have time to adjust in response to either turning an additional fan on or off. In some respects, this delay time may be referred to as a soaking time in which the components are allowed to adjust to transient changes in operating conditions, such as turning at least one of the fans either off or on.

After waiting for the specified delay time in step 520, the controller may perform the above describes steps again starting at step 502 to control thermal levels inside the housing. However, if use of the forced airflow control device is no longer needed or desired, the process ends.

Although FIG. 5 illustrates one example of a method 500 for controlling the forced airflow control device, various changes may be made to FIG. 5. For example, while shown as a series of steps, various steps in FIG. 5 could overlap, occur in parallel, occur in a different order, or occur multiple times.

In some embodiments, various functions described above are implemented or supported by a computer program that is formed from computer readable program code and that is embodied in a computer readable medium. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with” and its derivatives mean to include, be included within, interconnect with, contain, be contained within, connect to or with, couple to or with, be communicable with, cooperate with, interleave, juxtapose, be proximate to, be bound to or with, have, have a property of, have a relationship to or with, or the like.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A forced airflow control device comprising:
a plurality of one-way valves for each of a plurality of fans that are configured to provide airflow to an enclosure of a housing, each one-way valve mounted over a port of its corresponding fan and configured to restrict the movement of the airflow to only one direction through the port of its respective fan.

2. The device of claim 1, wherein the housing is configured to house an electronic circuit assembly.

3. The device of claim 1, wherein each one-way valves comprises:
at least two flaps coupled to the fans via hinges such that the flaps are movable between (i) a closed position adjacent the port and (ii) an open position away from the port.

4. The device of claim 3, wherein the flaps are biased in the closed position using springs.

5. The device of claim 3, further comprising a plurality of seals each associated with one of the one-way valves, the seals sandwiched between the flaps and a panel when the flaps are in the closed position.

6. The device of claim 1, further comprising a panel on which the fans and one-way valves are mounted.

7. The device of claim 1, further comprising a controller configured to turn off and turn on selective ones of the plurality of fans.

8. A thermal management system comprising:
a housing;
a plurality of fans each comprising a port and configured to provide an airflow to an enclosure of the housing; and
a plurality of one-way valves each associated with one of the fans, each one-way valve mounted over the port of its corresponding fan and configured to restrict movement of air through to only one direction through the port.

9. The thermal management system of claim 8, wherein the housing is configured to house an electronic circuit assembly.

10. The thermal management system of claim 8, wherein each one-way valves comprises:
a pair of flaps coupled to the fans via hinges such that the flaps are movable between (i) a closed position adjacent the port and (ii) an open position away from the port.

11. The thermal management system of claim 10, wherein the flaps are biased in the closed position using springs.

12. The thermal management system of claim 10, further comprising a plurality of seals each associated with one of the one-way valves, the seals sandwiched between the flaps and a panel when the flaps are in the closed position.

13. The thermal management system of claim 8, further comprising a controller configured to turn off and turn on selective ones of the plurality of fans.

14. A thermal management method comprising:
acquiring a temperature measurement of one or more components configured inside a housing, the housing comprising a plurality of fans configured to provide an airflow to the one or more components, each fan comprising a port through which the fan forces an airflow into the housing, and a plurality of one-way valves each associated with one of the fans, each one-way valve mounted over the port of its corresponding fan and configured to restrict the movement of air through to only one direction through the port; and
selectively turning on or off, one or more of the fans to control a temperature of the one or more components inside the housing.

15. The thermal management method of claim 14, further comprising:
when all the fans are powered on and the temperature exceeds a specified upper threshold level, generating an over-temperature alarm.

16. The thermal management method of claim 14, further comprising:
when all the fans are powered off and the temperature goes below a specified lower threshold level, generating an under-temperature alarm.

17. The thermal management method of claim 14, wherein the housing houses an electronic circuit assembly.

18. The thermal management method of claim 14, further comprising biasing the flaps in the closed position using springs.

19. The thermal management method of claim 14, further comprising a plurality of seals each associated with one of the one-way valves, the seals sandwiched between the flaps and a panel when the flaps are in the closed position.

20. The thermal management method of claim 14, further comprising mounting the fans and one-way valves on a panel.
